(19) United States
(12) Patent Application Publication
(10) Pub. No.: US 2025/0062141 A1
(43) Pub. Date: Feb. 20, 2025

(54) SYSTEM AND METHOD FOR WAFER WET PROCESS

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Jie CHEN, Shanghai City (CN); Chuang LI, Shanghai City (CN); Qiang SU, Shanghai City (CN); Haobo NI, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/459,165

(22) Filed: Aug. 31, 2023

(30) Foreign Application Priority Data
Aug. 18, 2023 (CN) 202311047474.7

(51) Int. Cl. H01L 21/67; H01L 21/02; H01L 21/677

(52) U.S. Cl. CPC H01L 21/67086; H01L 21/02019; H01L 21/67253; H01L 21/67259; H01L 21/67742

(57) ABSTRACT

A method includes placing a wafer in a process bath filled with a process solution; determining whether the wafer is in the process bath after a pre-set process time after placing the wafer in the process bath; and in response the determination determines that the wafer is in the process bath after the pre-set process time, draining the process solution from the process bath while the wafer is in the process bath.

### PRIORITY CLAIM AND CROSS-REFERENCE

This application claims priority to China Application Serial Number 202311047474.7, filed Aug. 18, 2023, which is herein incorporated by reference.

### BACKGROUND

Semiconductor devices are formed on wafers using a manufacturing process that includes several wet processing operations, such as etching operations and rinsing operations. The wet processing operations placing wafers in a bath filled with liquids. The liquids in the bath may react with a material such as a film or other material being etched or removed. The wet processing operations are ended by take the wafer away from the bath by robot arms on time.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a wet processing method according to some embodiments of the present disclosure.

FIGS. 2A and 2B are cross-sectional views at various stages of manufacturing a semiconductor device according to some embodiments of the present disclosure.

FIGS. 3A-3C are diagrammatic cross-sectional views of a wet etch apparatus at various stages of a wet processing method according to some embodiments of the present disclosure.

FIG. 4 is a wafer rescuing process applicable to end a wet etch process according to some embodiments of the present disclosure.

FIGS. 5A and 5B are cross-sectional views at various stages of manufacturing a semiconductor device according to some embodiments of the present disclosure.

FIGS. 6A-6C are diagrammatic cross-sectional views of a rinse apparatus at various stages of a wet processing method according to some embodiments of the present disclosure.

FIG. 7 is a wafer rescuing process applicable to end a wet rinse process according to some embodiments of the present disclosure.

FIG. 8 is a block diagram of a system for a wafer wet process according to some embodiments of the present disclosure.

FIG. 9A is a block diagram of a system for a wafer wet process under an automatic mode according to some embodiments of the present disclosure.

FIG. 9B is a block diagram of a system for a wafer wet process under a manual mode according to some embodiments of the present disclosure.

FIG. 9C is a block diagram of a system for a wafer wet process under an emergency mode according to some embodiments of the present disclosure.

FIG. 10A is a diagrammatic view of a control module according to some embodiments of the present disclosure.

FIG. 10B is a top view of an air pipe output panel of the control module of FIG. 9A.

FIG. 10C is a top view of a manual button panel of the control module of FIG. 9A.

FIG. 11 is a flow chart of a method for automatically controlling a wet etch/rinse apparatus according to some embodiments of the present disclosure.

FIG. 12 is a chart showing various operations of a control module under a manual mode according to some embodiments of the present disclosure.

FIG. 13 is a circuit diagram of an emergency mode according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

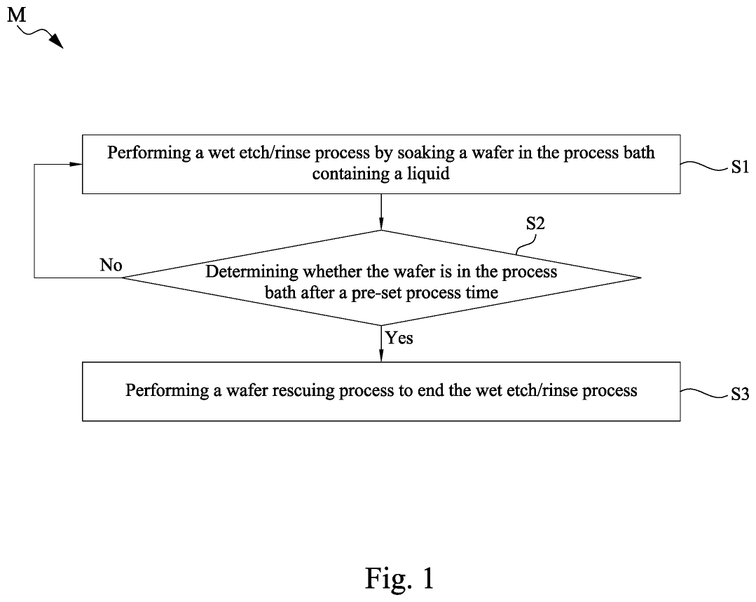

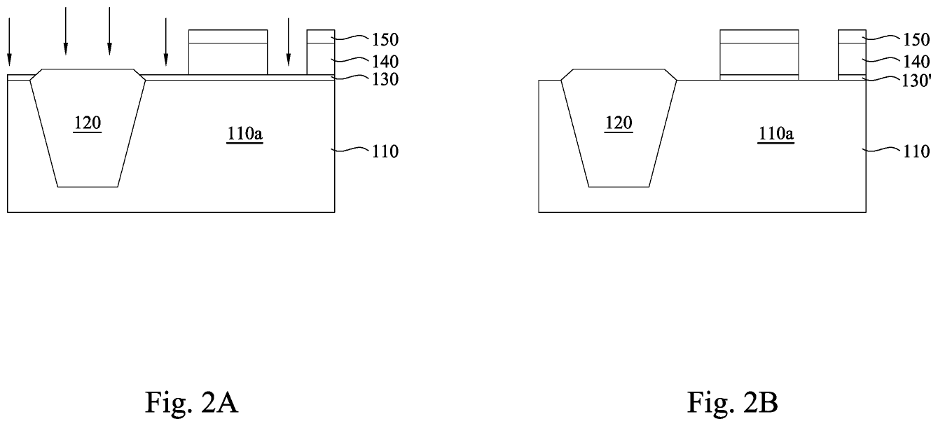

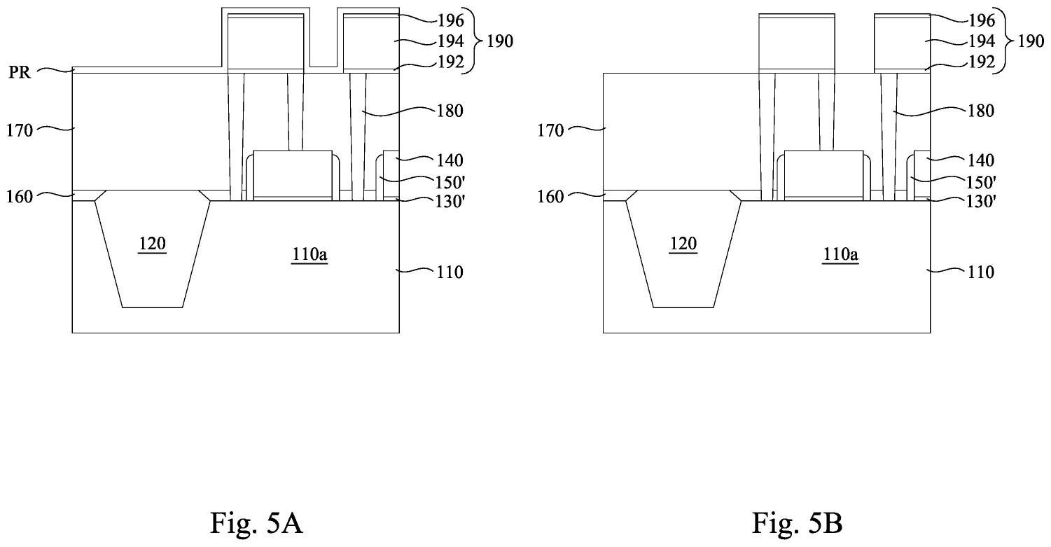

FIG. 1 is a flow chart of a wet processing method M according to some embodiments of the present disclosure. The wet processing method M includes performing a wafer etch/rinse process by soaking a wafer in the process bath containing a liquid at step S1; determining whether the wafer is in the process bath after a pre-set process time at step S2; when the wafer is in the process bath after a pre-set process time, performing a wafer rescuing process to end the wet etch/rinse process at step S3; when the wafer is not in the process bath after a pre-set process time, the method goes back to step S1. It is understood that additional steps may be provided before, during, and after the steps shown in FIG. 1, and some of the steps described can be replaced or eliminated for additional embodiments of the method. The order of the operations/processes may be interchangeable. The wet processing method M for the wet etch process is discussed further below with exemplary embodiments as shown in FIGS. 2A-4. The wet processing method M for the wet rinse process is discussed further below with exemplary embodiments as shown in FIGS. 5A-7.

FIGS. 2A and 2B are cross-sectional views at various stages of manufacturing a semiconductor device according to some embodiments of the present disclosure. Reference is made to FIG. 2A. A semiconductor substrate 110 is provided. An isolation structure 120 is formed over the semiconductor substrate 110 for defining active regions 110a. A gate dielectric layer 130 is formed over the semiconductor substrate 110. A gate stack including a gate electrode 140 and a hard mask 150 is formed over the gate dielectric layer 130. The semiconductor substrate 110 may include suitable semiconductor material, such as silicon. The isolation structure 120 may include one or more suitable dielectric materials, such as silicon oxide, silicon nitride, silicon oxynitride, the like, or the combination thereof. The gate dielectric layer 130 may include suitable dielectric materials, such as silicon oxide, the like, or the combination thereof. The gate electrode 140 may include polysilicon. The hard mask 150 may include suitable hard mask materials, such as silicon nitride.

Reference is made to FIG. 2B. The gate dielectric layer 130 (referring to FIG. 2A) is patterned into a gate dielectric 130′ by a wet etch process by using the hard mask 150 as an etch mask. By the wet etch process, portions of the gate dielectric layer 130 (referring to FIG. 2A) uncovered by the hard mask 150 are removed, and a portion of the gate dielectric layer 130 (referring to FIG. 2A) below the hard mask 150 remains and forms the gate dielectric 130′. The wet processing method M illustrated in FIG. 1 can be used when patterning the gate dielectric layer 130.

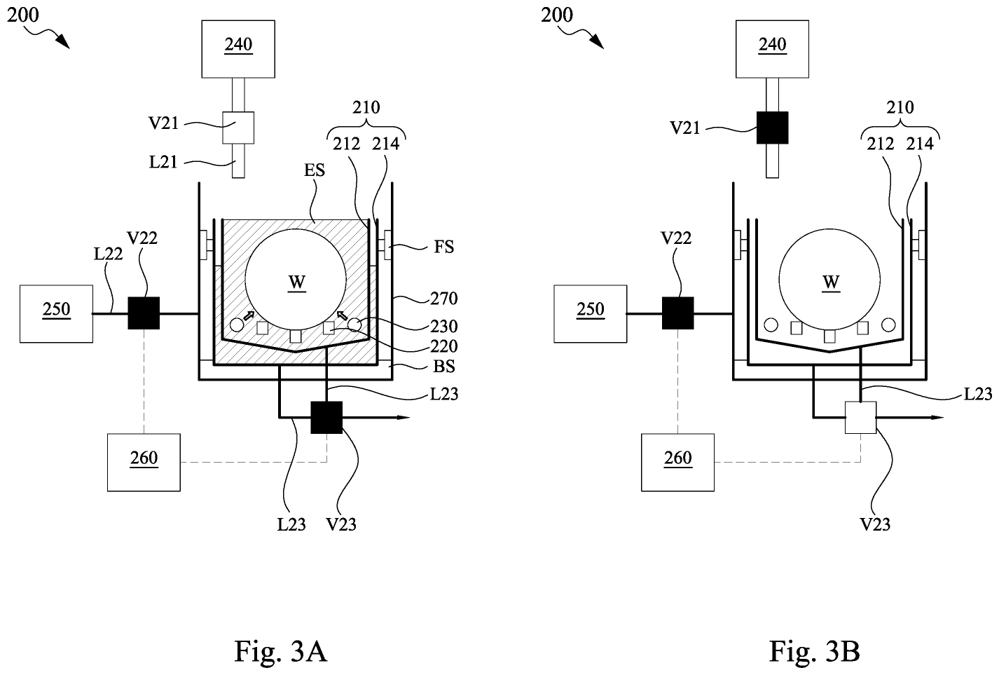

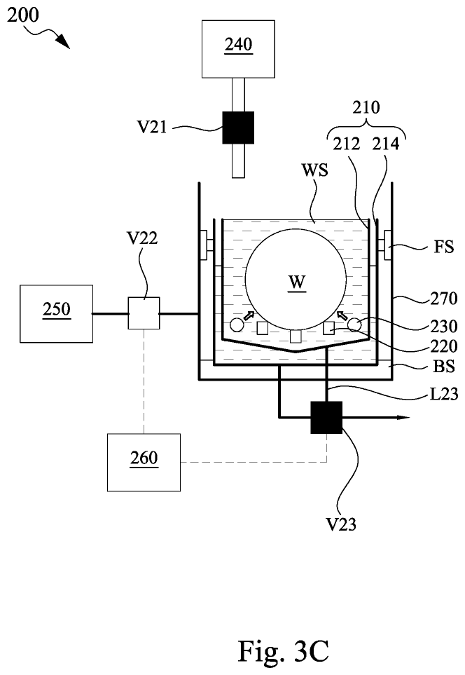

Referring to FIGS. 1, 2B, and 3A, the method begins at step S1, the wet etch process is performed by soaking a wafer W in the process bath 210 containing a liquid (e.g., the etching solution ES). FIGS. 3A-3C are diagrammatic cross-sectional views of a wet etch apparatus 200 at various stages of a wet processing method M according to some embodiments of the present disclosure. The wafer W includes one or plural semiconductor substrates 110 in FIGS. 2A and 2B. For example, under the control of the controller 260, the etching solution ES is supplied from the etching solution source 240 to the process bath 210 through the flow control device V21 and the supply line L21. For removing silicon oxide layer, the etching solution ES may be HF and buffered oxide etchant (BOE). In some alternative embodiments, the etching solution ES may be ammonia-peroxide mixture (APM) (e.g., a mixture of NH₄OH, H₂O₂, and water), H₃PO₄, the like, or the combination thereof. If the wafer W is soaked too long, the portion of the gate dielectric layer 130 below the hard mask 150 could be laterally etched, and over-etch issues occurs in the gate dielectrics 130′, which may make the gate dielectrics 130′ easily break down. For avoiding the over-etch issues, a pre-set process time in which the wafer W is soaked in the process bath 210 may be determined in advance. The pre-set process time may be determined in advance depending on the process requirements. For example, the pre-set process time may be in a range from about 1 second to about 30 minutes for the wet etch process depending on the process requirements. The pre-set process time can be modified by the toleration time before a wafer rescuing process when a wafer process time exceeds the pre-set time unexpectedly. The pre-set process time may also be referred to as a etch duration for the wet etch process.

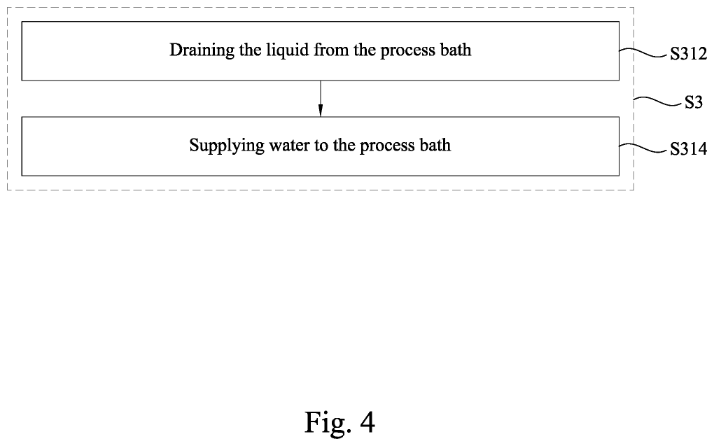

The method proceeds to step S2, a determination is made whether the wafer W is in the process bath 210 at a time point after the pre-set process time after placing the wafer W in the process bath 210. For example, suitable sensors may be used to inspect the presence of the wafers W in the process bath 210. If the determination determines that the wafer W is not in the process bath 210 at a time point after the pre-set process time, the method goes back to step S1. If the determination determines that the wafer W is in the process bath 210 at a time point after the pre-set process time, a wafer rescuing process is performed to end the wet etch process at step S3, which can avoid over-etch issues. In the present embodiments of the wet etch process, the wafer rescuing process at step S3 may include steps S312 and S314, as described in FIG. 4.

Reference is made to FIG. 4 and FIG. 3B. The method proceeds to step S312, where the liquid (e.g., the etching solution ES in FIG. 3A) is drained from the process bath 210. For example, under the control of the controller 260, the etching solution ES in FIG. 3A is drained from the process bath 210 (e.g., the inner bath 212 and/or the outer bath 214) through the flow control device V23 and the drain line L23. The duration for draining the etching solution ES from the process bath 210 may range from about 10 seconds to about 300 seconds. For example, for draining the BOE from the process bath 210, the duration may range from about 10 seconds to about 30 seconds. For example, for draining the APM from the process bath 210, the duration may range from about 30 seconds to about 60 seconds. For example, for draining the H₃PO₄ from the process bath 210, the duration may range from about 120 seconds to about 300 seconds.

Reference is made to FIG. 4 and FIG. 3C. The method proceeds to step S314, where the inactive solution WS is supplied to the process bath 210. The inactive solution WS is inactive to the wafer W. For example, the inactive solution WS may be de-ionized (DI) water. For example, after the etching solution ES (referring to FIG. 3A) is drained from the process bath 210, under the control of the controller 260, the inactive solution WS is supplied from the water source 250 to the process bath 210 (e.g., the inner bath 212) through the flow control device V22 and the supply line L22. The duration for supplying the inactive solution WS to the process bath 210 may range from about 40 seconds to about 120 seconds.

Through the wafer rescuing process including steps S312 and S314, the wafer W in the process bath 210 is spaced apart from the etching solution ES, thereby addressing over-etching issues.

In FIGS. 3A-3C, the wet etch apparatus 200 includes a process bath 210, wafer holders 220, supplying nozzles 230, an etching solution source 240, a water source 250, a controller 260, a sink tank 270, flow control devices V21-V23, lines L21-L23, and support elements FS.

The process bath 210 stores an etching solution ES. The process bath 210 includes an inner bath 212 and an outer bath 214. An etching solution ES overflowing from the inner bath 212 flows into the outer bath 214. The liquid level in the outer bath 214 is maintained lower than the liquid level in the inner bath 212. The wafer holders 220 are disposed in the inner bath 212 for holding one or plural wafers W. The process bath 210 can be fixed in the sink tank 270 by the support elements FS. The sink tank 270 may contain suitable solution BS for buffering etching solution ES. For example, the solution BS may be DI-water.

The supplying nozzles 230 are disposed in the inner bath 212 and fluidly connected to the outer bath 214 by a suitable circulation line with a pump. By driving the pump, a circulation flow of the liquids (e.g., etching solution ES or de-ionized water) is formed, which flows from the outer bath 214 through the circulation line and the supplying nozzles 230 into the inner bath 212. Arrows adjacent the supplying nozzles 230 indicates the flow direction of the etching solution ES coming from the supplying nozzles 230.

An etching solution supplying system includes an etching solution source 240, a supply line L21 coupled to the etching solution source 240, and a flow control device V21 coupled to the supply line L21. The etching solution source 240 includes a tank storing the etching solution ES. Via the flow control device V21 and the supply line L21, the etching solution source 240 provides the etching solution ES to the process bath 210 (e.g., the inner bath 212 and/or the outer bath 214).

A water supplying system includes a water source 250, a supply line L22 coupled to the water source 250, and a flow control device V22 coupled to the supply line L22. The water source 250 includes a tank storing water, such as de-ionized water (DI-water). Via the flow control device V22 and the supply line L22, the water source 250 provides water to the inner bath 212.

One or plural drain lines L23 are fluidly couple to a bottom of the inner bath 212 and/or a bottom of the outer bath 214. For example, the inner bath 212 and the outer bath 214 have drain holes at their bottoms, and the drain lines L23 are fluidly coupled to the drain holes. The flow control device V23 is coupled to the drain lines L23. Via the flow control device V23 and the drain lines L23, liquids (e.g., the etching solution ES) can be drained out from the inner bath 212 and/or the outer bath 214.

In present embodiments, the flow control devices V21-V23 may be pneumatic valves. In some other embodiments, the flow control devices V21-V23 may be a shutoff valves, a flow control valves, flowmeters, the like, or the combination thereof. The controller 260 may control the flow control devices V21-V23 for adjusting the flow rates of the lines L21-L23. The controller 260 may include a computer-readable storage medium and a processor coupled to the computer-readable storage medium. The computer-readable storage medium stores program that controls various steps of the wet processing method M performed in the wet etch apparatus 200. The controller 260 controls the operations of the wet etch apparatus 200 by using the processor reading out and executing the program stored in the storage medium. The program may be one that has been stored in the computer-readable storage medium, or may be one that has been installed to the storage medium of the controller 260.

FIGS. 5A and 5B are cross-sectional views at various stages of manufacturing a semiconductor device according to some embodiments of the present disclosure. Reference is made to FIG. 5A. As aforementioned, the isolation structure 120 is formed over the semiconductor substrate 110 for defining active regions 110a. The gate dielectric 130′ and the gate electrode 140 are formed over the active regions 110a. Gate spacers 150′ are formed on opposite sides of the stack of the gate dielectric 130′ and the gate electrode 140. An etch stop layer 160 and an interlayer dielectric layer 170 can be deposited over the semiconductor substrate 110. Contacts 180 are formed in the interlayer dielectric layer 170 over the gate electrode 140 and source/drain regions of the active regions 110a. Conductive features 190 are formed over the contacts 180. The conductive features 190 may serve as conductive features (e.g., conductive lines) in plural metallization layers of an interconnect structure.

The conductive features 190 may include a first metal layer 192, a second metal layer 194, and a third metal layer 196. For example, the first and third metal layers 192 and 196 are titanium nitride (TiN) layers, and the second metal layer 194 is an aluminum copper (AlCu) layer. Formation of the conductive features 190 may include depositing a first TiN film, an AlCu film, depositing a second TiN film in a sequence, forming photomasks over the films by photolithography process, and patterning the films through the photomasks by etching process. After the formation of the conductive features 190, the photomasks are removed by stripping process using suitable strippers. After the formation of the conductive features 190, residues PR may be left on top surfaces of the conductive features 190 and sidewalls of the conductive features 190. The residues PR may come from materials of the photomasks and the strippers.

Reference is made to FIG. 5B. A wet rinse process is performed to remove the residues PR from the top surfaces of the conductive features 190 and sidewalls of the conductive features 190. The wet processing method M illustrated in FIG. 1 can be used for rinsing the semiconductor substrate 110.

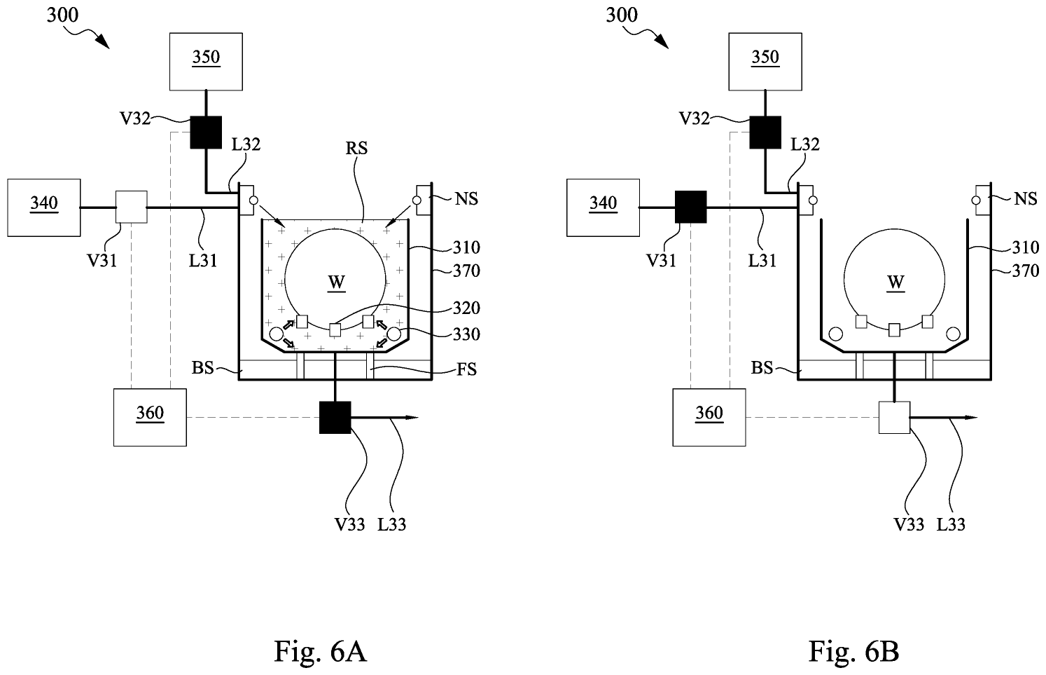

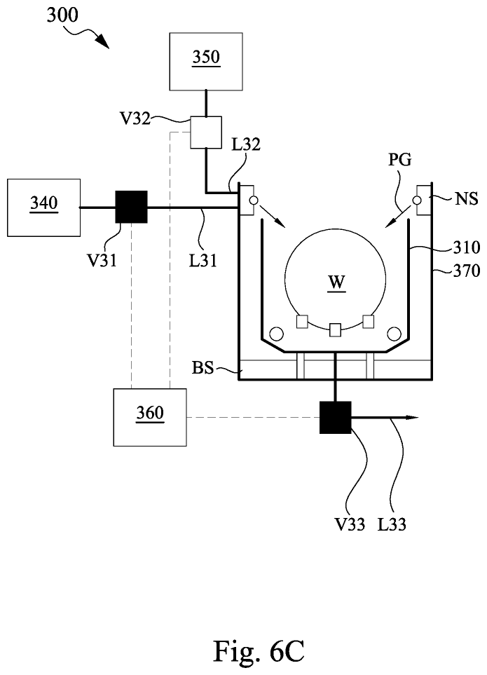

Referring to FIGS. 1, 5B, and 6A, the method begins at step S1, the wet rinse process is performed by soaking a wafer W in the process bath 310 containing a liquid (e.g., the rinsing solution RS). FIGS. 6A-6C are diagrammatic cross-sectional views of a rinse apparatus 300 at various stages of a wet processing method according to some embodiments of the present disclosure. The wafer W includes one or plural semiconductor substrates 110 in FIGS. 5A and 5B. For example, under the control of the controller 360, the rinsing solution RS is supplied from the rinsing solution source 340 to the process bath 310 through the flow control device V31 and the supply line L31. In some embodiments, the rinsing solution RS may be a DI-water, the like, or the combination thereof.

The process bath 310 may be a quick dump rinse (QDR) tank, a final rinse (FR) tank, or a dryer (e.g., for Marangoni dry). In some embodiments, the wafer W may be processed by several wet rinse processes in a sequence. For example, a QDR process, a FR process, and a Marangoni dry process are performed in a sequence for rinsing the wafer W. The QDR process is performed to first remove the residues PR. The FR process is performed after the QDR process to ensure the residues PR are completely removed. The Marangoni dry process is performed after the FR process to dry the wafer W. In each of the QDR process, the FR process, and the Marangoni dry process, the wafer W is soaked by the rinsing solution RS (e.g., DI-water). If the wafer W is soaked too long, the rinsing solution RS (e.g., DI-water) may consume or etch AlCu (e.g., the second metal layer 194), over-dipping issues occurs in AlCu (e.g., the second metal layer 194), which may make the resistivity of metal lines get higher. For avoiding the over-dipping issues, a pre-set process time may be determined for each wet rinse process in advance. The pre-set process time may be determined in advance depending on the process requirements. For example, the pre-set process time may be in a range from about 1 second to about 60 minutes for the wet rinse process depending on the process requirements. The pre-set process time can be modified by the toleration time before a wafer rescuing process when a wafer process time exceeds the pre-set time unexpectedly. The pre-set process time may also be referred to as a rinse duration for the wet rinse process.

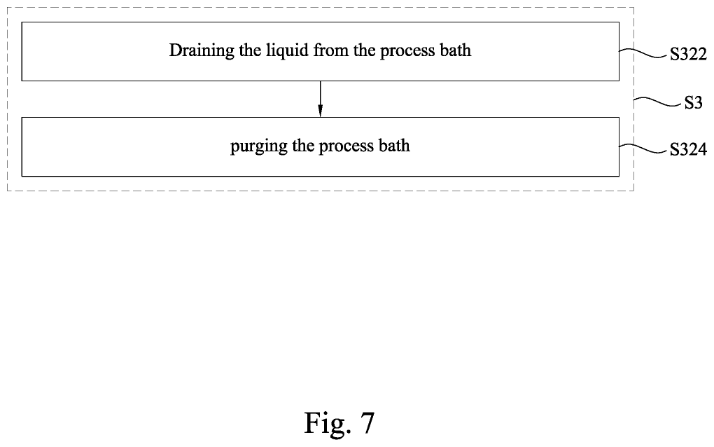

The method proceeds to step S2, a determination is made whether the wafer W is in the process bath 310 at a time point after a pre-set process time after placing the wafer W in the process bath 310. For example, suitable sensors may be used to inspect the presence of the wafers W in the process bath 310. If the determination determines that the wafer W is not in the process bath 310 at a time point after the pre-set process time, the method goes back to step S1. If the determination determines that the wafer W is in the process bath 210 at a time point after the pre-set process time, a wafer rescuing process is performed to end the wet rinse process at step S3, which can avoid over-dipping issues. In the present embodiments of the wet etch process, the wafer rescuing process at step S3 may include steps S322 and S324, as described in FIG. 7.

Reference is made to FIG. 7 and FIG. 6B. The method proceeds to step S322, where the liquid (e.g., the rinsing solution RS in FIG. 6A) is drained from the process bath 310. For example, under the control of the controller 360, the rinsing solution RS in FIG. 6A is drained from the process bath 310 through the flow control device V33 and the drain line L33. The duration for draining the rinsing solution RS may range from about 5 seconds to about 30 seconds. For example, for draining the rinsing solution RS from the QDR tank, the duration may range from about 5 seconds to about 10 seconds. For example, for draining the rinsing solution RS from the FR tank, the duration may range from about 10 seconds to about 30 seconds. For example, for draining the rinsing solution RS from the dryer tank, the duration may range from about 5 seconds to about 10 seconds.

Reference is made to FIG. 7 and FIG. 6C. The method proceeds to step S324, where the process bath 310 is purged. For example, after the rinsing solution RS (referring to FIG. 6A) is drained from the process bath 310, under the control of the controller 360, a gas PG is supplied from the gas source 350 to the spraying nozzles NS through the flow control device V32 and the supply line L32, and the spraying nozzles NS can spay the gas PG toward the process bath 310, thereby purging the process bath 310. The duration for purging the process bath 310 may be greater than 100 seconds, for example, at about 300 seconds.

Through the wafer rescuing process including steps S322 and S324, the wafer W in the process bath 310 is spaced apart from the rinsing solution RS, thereby addressing over-dipping issues.

In FIGS. 6A-6C, the rinse apparatus 300 includes a process bath 310, wafer holders 320, supplying nozzles 330, a rinsing solution source 340, a gas source 350, a controller 360, a sink tank 370, flow control devices V31-V33, lines L31-L33, spraying nozzles NS, and support elements FS.

The process bath 310 stores a rinsing solution RS. The wafer holders 320 are disposed in the process bath 310 for holding one or plural wafers W. The process bath 310 can be fixed in the sink tank 370 by the support elements FS. The sink tank 370 may contain suitable solution BS, such as DI-water.

The supplying nozzles 330 are disposed in the process bath 310 fluidly connected with a pump. By driving the pump, a circulation flow of the liquids (e.g., rinsing solution RS) is formed, which flows into the process bath 310. Arrows adjacent the supplying nozzles 330 indicates the flow direction of the rinsing solution RS coming from the supplying nozzles 330.

A rinsing solution supplying system includes a rinsing solution source 340, spraying nozzles NS, a supply line L31 coupled between the rinsing solution source 340 and the spraying nozzles NS, and a flow control device V31 coupled to the supply line L31. The rinsing solution source 340 includes a tank storing the rinsing solution RS. Via the flow control device V31 and the supply line L31, the rinsing solution source 340 provides the rinsing solution RS to the spraying nozzles NS, and the spraying nozzles NS can dispense the rinsing solution RS toward the process bath 310.

A gas supplying system includes a gas source 350, a supply line L32 coupled between the gas source 350 and the spraying nozzles NS, and a flow control device V32 coupled to the supply line L32. The gas source 350 stores a suitable purging gas, such as clean dry air (CDA). For example, the gas source 350 may store nitrogen gas. Via the flow control device V32 and the supply line L32, the gas source 350 provides water to the spraying nozzles NS, and the spraying nozzles NS can dispense the purging gas toward the process bath 310.

One or plural drain lines L33 are couple to a bottom of the process bath 310. The flow control device V33 is coupled to the drain line L33. For example, the process bath 310 has a drain hole at its bottoms, and the drain line L33 is fluidly coupled to the drain holes. Via the flow control device V33 and the drain line L33, liquids (e.g., the rinsing solution RS) can be drained out from the process bath 310.

In present embodiments, the flow control devices V31-V33 may be pneumatic valves. In some other embodiments, the flow control devices V31-V33 may be a shutoff valves, a flow control valves, flowmeters, the like, or the combination thereof. The controller 360 may control the flow control devices V31-V33 for adjusting the flow rate of the lines L31-L33. The controller 360 may include a computer-readable storage medium and a processor coupled to the computer-readable storage medium. The computer-readable storage medium stores program that controls various steps of the wet processing method M performed in the rinse apparatus 300. The controller 360 controls the operations of the rinse apparatus 300 by using the processor reading out and executing the program stored in the storage medium. The program may be one that has been stored in the computer-readable storage medium, or may be one that has been installed to the storage medium of the controller 360.

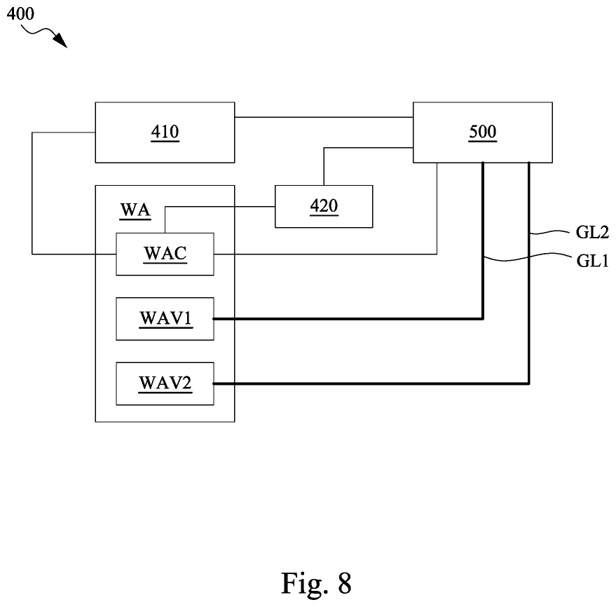

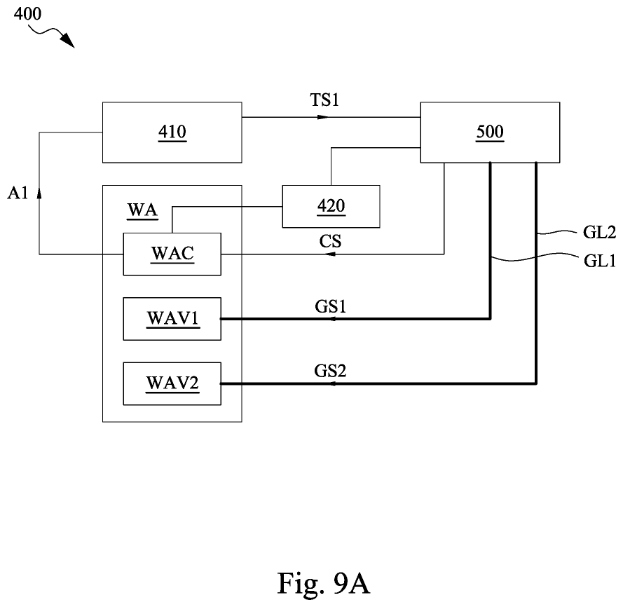

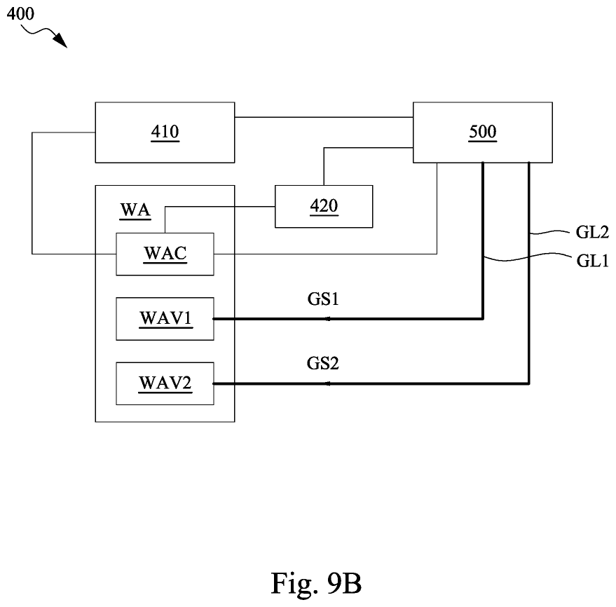

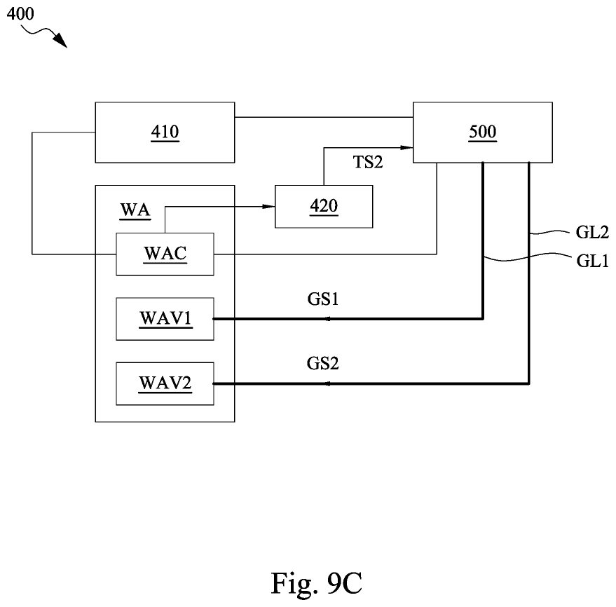

FIG. 8 is a block diagram of a system 400 for a wafer wet process according to some embodiments of the present disclosure. The system 400 includes a wet process apparatus WA, a central server 410, and a control module 500. The wet process apparatus WA may include various flow control devices WAV1 and WAV2 and a controller WAC. In some embodiments, the wet process apparatus WA may correspond to the wet etch apparatus 200 in FIGS. 3A-3C, in which the flow control devices WAV1 and WAV2 respectively correspond to the flow control device V22 and V23 in FIGS. 3A-3C, and the controller WAC corresponds to the controller 260 in FIGS. 3A-3C. In some embodiments, the wet process apparatus WA may correspond to the rinse apparatus 300 in FIGS. 6A-6C, in which the flow control devices WAV1 and WAV2 respectively correspond to the flow control device V32 and V33 in FIGS. 6A-6C, and the controller WAC corresponds to the controller 360 in FIGS. 6A-6C. The control module 500 can be operated in an automatic mode (referring to FIG. 9A), a manual mode (referring to FIG. 9B), and an emergency mode (referring to FIG. 9C).

FIG. 9A is a block diagram of a system for a wafer wet process under an automatic mode according to some embodiments of the present disclosure. The controller WAC of the wet process apparatus WA can send real-time signals to the central server 410 to indicate the conditions of the wet process apparatus WA. For example, the real-time signals are obtained from sensors that inspect the presence of the wafers W in the process bath. In some embodiments, when odds occur in the real-time signals, the controller WAC of the wet process apparatus WA can send an alarm message/signal A1 to the central server 410 to indicate an abnormal condition of the wet process apparatus WA. Then, the central server 410 can check if the alarm signal A1 is of specified alarm signals. If the alarm signal A1 is of the specified alarm signals, the central server 410 can send a trigger signal TS1 to the control module 500. In the automatic mode, the control module 500 can receive commands (e.g., the trigger signal TS1) from the central server 410 and be triggered to stop wafer loading and perform a wafer rescuing program.

For stopping wafer loading, for some kinds of the wet process apparatus WA, the control module 500 can send a signal CS to the controller WAC of the wet process apparatus WA to stop receiving wafer, thereby stopping wafer loading. For some other kinds of the wet process apparatus WA, the wet process apparatus WA may stop itself once it sends the alarm signal A1.

Through the wafer rescuing program, the control module 500 can control the gas flows provided by the gas lines GL1 and GL2, thereby control the flow control devices WAV1 and WAV2 of the wet process apparatus WA via the gas lines GL1 and GL2. In some embodiments for wet etch process, through the wafer rescuing program, the control module 500 can send gas GS1 to turn on the flow control device WAV1 (e.g., the flow control device V23 in FIG. 3B) through the gas line GL1, thereby draining liquids from process tube, as illustrated in FIG. 3B. Then, through the wafer rescuing program, the control module 500 can send gas GS2 to turn on the flow control device WAV2 (e.g., the flow control device V22 in FIG. 3C) through the gas line GL2, thereby supplying water to the process tube, as illustrated in FIG. 3C. These steps of the wafer rescuing program accomplish the wafer rescuing process in the wet etch process. In some embodiments for rinse process, through the wafer rescuing program, the control module 500 can send gas GS1 to turn on the flow control device WAV1 (e.g., the flow control device V33 in FIG. 6B) through the gas line GL1, thereby draining liquids from process tube, as illustrated in FIG. 6B. Then, through the wafer rescuing program, the control module 500 can send gas GS2 to turn on the flow control device WAV2 (e.g., the flow control device V32 in FIG. 6C) through the gas line GL2, thereby supplying gas PG to purge the process tube, as illustrated in FIG. 6C. These steps of the wafer rescuing program accomplish the wafer rescuing process in the rinse process.

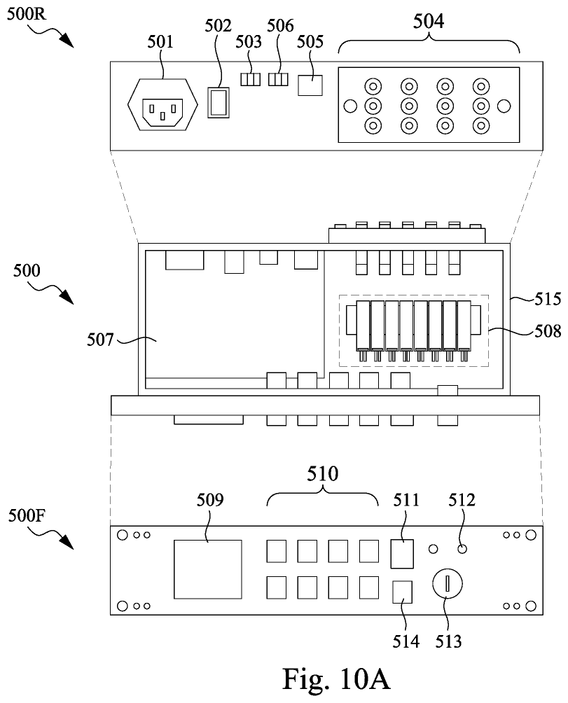

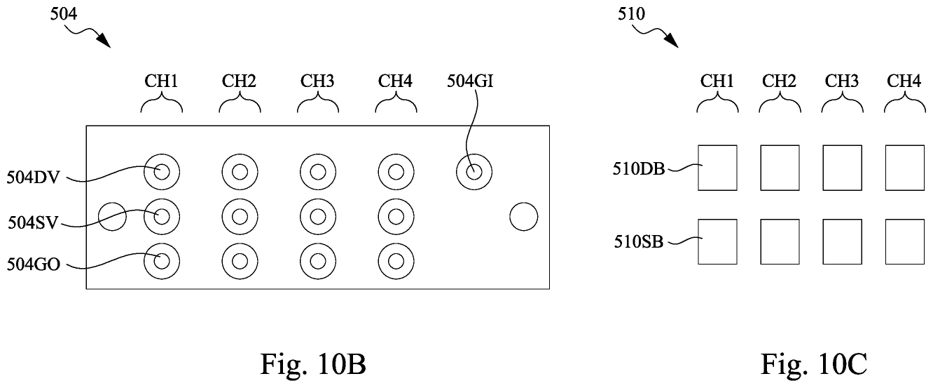

FIG. 9B is a block diagram of a system for a wafer wet process under a manual mode according to some embodiments of the present disclosure. In the manual mode, the control module 500 can receive commands from a user (e.g., by the manual button panel 510 in FIG. 10A), and then control the flow control devices WAV1 and WAV2 of the wet process apparatus WA via the gas lines GL1 and GL2 according to the received commands from the user. In some embodiments, in the manual mode, the control module 500 can receive commands from a user to perform a wafer rescuing program (e.g., by the manual button panel 510 and/or the liquid crystal display (LCD) touch screen 509 in FIG. 10A).

FIG. 9C is a block diagram of a system for a wafer wet process under an emergency mode according to some embodiments of the present disclosure. The system 400 may optionally include a monitor device 420 electrically connected to the controller WAC of the wet process apparatus WA. When the monitor device 420 detects power breakdown in the wet process apparatus WA, and the monitor device 420 sends a trigger signal TS2 to the control module 500, to initiate the emergency mode and trigger the control module 500 to perform the wafer rescuing program.

The control module 500 can control gas flows provided by the gas lines GL1 and GL2 through the wafer rescuing program, thereby control the flow control devices WAV1 and WAV2 of the wet process apparatus WA via the gas lines GL1 and GL2. As aforementioned in FIG. 9A, in some embodiments for wet etch process, through the wafer rescuing program, the control module 500 can send gas GS1 to turn on the flow control device WAV1 (e.g., the flow control device V23 in FIG. 3B) through the gas line GL1, thereby draining liquids from process tube, as illustrated in FIG. 3B. Then, through the wafer rescuing program, the control module 500 can send gas GS2 to turn on the flow control device WAV2 (e.g., the flow control device V22 in FIG. 3C) through the gas line GL2, thereby supplying water to the process tube, as illustrated in FIG. 3C. These steps accomplish the wafer rescuing process in the wet etch process. As aforementioned in FIG. 9A, in some embodiments for rinse process, through the wafer rescuing program, the control module 500 can send gas GS1 to turn on the flow control device WAV1 (e.g., the flow control device V33 in FIG. 6B) through the gas line GL1, thereby draining liquids from process tube, as illustrated in FIG. 6B. Then, through the wafer rescuing program, the control module 500 can send gas GS2 to turn on the flow control device WAV2 (e.g., the flow control device V32 in FIG. 6C) through the gas line GL2, thereby supplying gas PG to purge the process tube, as illustrated in FIG. 6C. These steps accomplish the wafer rescuing process in the rinse process.

FIG. 10A is a diagrammatic view of a control module 500 according to some embodiments of the present disclosure. FIG. 10A illustrated a plan view of the control module 500 with a front-side view showing a front panel 500F of the control module 500 and a back-side view showing a rear panel 500R of the control module 500.

At the front panel 500F, the control module 500 includes a power input jack 501, a controller power switch 502, an interlock interface 503, an air pipe output panel 504, a communication interface 505, and an emergency mode trigger signal interface 506. At the back panel 500R, the control module 500 includes a liquid crystal display (LCD) touch screen 509, a manual button panel 510, a buzzer 511, a mode indicator 512, a mode switch 513, and alarm and program reset button 514. The control module 500 further includes a microcontroller unit (MCU) board 507, a group of solenoid valves 508, and a metal shell 515. In some embodiments, the control module 500 may further include a printed circuit board for providing electrical connection among the various elements of the control module 500.

The power input jack 501 is an electrical connector for supplying power to various loads of the control module 500, such as the MCU board 507, the solenoid valves 508, the air pipe output panel 504, the LCD touch screen 509, the manual button panel 510, the buzzer 511, a mode indicator 512, a mode switch 513, and alarm and program reset button 514. For example, the power input jack 501 is power cord socket. The controller power switch 502 manages the supply of power by creating an electrical connection from the power input jack 501 to the various loads of the control module 500.

The solenoid valves 508 are electromechanically operated valves. In some embodiments, the solenoid valves 508 are used to control the gas flow from the air pipe output panel 504. For example, the solenoid valves 508, when electrically energized or de-energized, are used to respectively shut off or allow the gas flows from the air pipe interfaces of the channels of the air pipe output panel 504 (e.g., air pipe interfaces 504DV and 504SV in FIG. 10B). The metal shell 515 are used to accommodate various elements of the control module 500, such as the MCU board 507 and the solenoid valves 508.

In some embodiments, the mode switch 513 is a physical switch used to switch modes of the control module 500. For example, the mode switch 513 can switch from an automatic mode to a manual mode; or from a manual mode to an automatic mode. The mode indicator 512 can show the current mode of the control module 500, such as the automatic mode, the manual mode, or an emergency mode.

The emergency mode trigger signal interface 506 can be an input interface electrically connected to the monitor device 420 for monitoring the condition of the wet process apparatus WA. For example, the monitor device 420 can be a programmable logic controller (PLC) relay sensor detecting a power supply condition or a CPU error, a time relay sensor detecting a heartbeat signal, or some devices detecting other specified signals in the wet process apparatus WA. For example, the monitor device 420 can be electrically connected to a power rail, a CPU error monitoring line, or a heartbeat signal node of the wet process apparatus WA. If an electrical or mechanical system fail occurs in the wet process apparatus WA, the monitor device 420 may detect power breakdown or no heartbeat signal in the wet process apparatus WA, and then the control module 500 would initiate the emergency mode when receiving a trigger signal from the monitor device 420 through the emergency mode trigger signal interface 506.

The MCU board 507 processes simple signals from various input interface, and send signals to the solenoid valves 508 to control the gas flow from the air pipe output panel 504. For example, when the control module 500 is at automatic mode, the MCU board 507 may receive a trigger signal TS1 from the central server 410 through the communication interface 505, and send signals to the solenoid valves 508 to control the gas flow from the air pipe output panel 504 according to the wafer rescuing program. The communication interface 505 may be a RJ45 interface. For example, when the control module 500 is at manual mode, the MCU board 507 may processes simple signals from the manual button panel 510, and send signals to the solenoid valves 508 to control the gas flow from the air pipe output panel 504 according to user's commands. For example, when the control module 500 is at emergency mode, the MCU board 507 may receive a trigger signal TS2 from the monitor device 420 through the emergency mode trigger signal interface 506, and send signals to the solenoid valves 508 to control the gas flow from the air pipe output panel 504 according to the wafer rescuing program.

The MCU board 507 may include a computer-readable storage medium and a processor coupled to the computer-readable storage medium. The computer-readable storage medium can store a wafer rescuing program that controls various steps of the wet processing process performed in the wet etch apparatus 200 and/or rinse apparatus 300. For example, in some embodiments for the wet etch process, the wafer rescuing program includes output a gas flow from the air pipe interface 504DV for the time duration for draining the etching solution ES, and output a gas flow from the air pipe interface 504SV for the time duration for supplying the inactive solution WS. In some embodiments for the wet etch process, the wafer rescuing program includes output a gas flow from the air pipe interface 504DV for the time duration for draining the rinsing solution RS, and output a gas flow from the air pipe interface 504GO for the time duration for purging the process bath. The MCU board 507 controls the operations of the wet etch apparatus 200 and/or rinse apparatus 300 by using the processor reading out and executing the wafer rescuing program stored in the storage medium. The wafer rescuing program may be one that has been stored in the computer-readable storage medium, or may be one that has been installed to the storage medium of the MCU board 507.

In some embodiments, the MCU board 507 may receive signals from the mode switch 513 and the emergency mode trigger signal interface 506 in advance, and determines the operation mode among the automatic mode (referring to FIG. 9A), the manual mode (referring to FIG. 9B), and the emergency mode (referring to FIG. 9C) accordingly. Then, the MCU board 507 may send signals to the solenoid valves 508 to control the gas flow from the air pipe output panel 504 according to the determined operation mode.

In some embodiments, the MCU board 507 can also send signals (e.g., the signals CS for stopping loading wafers in FIG. 9A) to the controller WAC of the wet process apparatus WA through an output interface, such as the interlock interface 503.

The LCD touch screen 509 is an input/output interface that displays parameters, conditions, and/or the operation mode of the control module 500, and allows an user to set or modify the programs controlling the air pipe output interfaces of the air pipe output panel 504 (e.g., the wafer rescuing programs) stored in the MCU board 507. For example, the user may set a program for one or more steps of draining the etching solution ES, supplying the inactive solution WS, draining the rinsing solution RS, and purging the process bath. In some examples, the user may set the time duration of steps of draining the etching solution ES, supplying the inactive solution WS, draining the rinsing solution RS, and purging the process bath.

The buzzer 511 may alarm when a trigger signal TS1/TS2 is received by the MCU board 507 of the control module 500, and a wafer rescuing process is triggered. The alarm and program reset button 514 is configured for ending the wafer rescuing program, stop alarm of the buzzer 511, and/or stop sending the alarm signal A1 to the central server 410.

The control module 500 has a self-diagnosis function that inspect a pressure, a power voltage, or other parameters. These inspected parameters of the control module 500 can be sent to the central server 410 (e.g., through the communication interface 505) for ensuring the condition of the control module 500. In some embodiments, the control module 500 can send an alarm signal to the central server 410 to indicate an abnormal condition of the control module 500. The central server 410 may be an computer integration manufacturing (CIM) system used for monitoring and controlling semiconductor fabrication processes among various apparatuses (such as plural wet process apparatuses WA). The central server 410 can be referred to as a factory sever. The central server 410 may be a computer device or program which manages and provides resources, data, services, or programs, over a network.

FIG. 10B is a top view of an air pipe output panel 504 of the control module 500 of FIG. 10A. Reference is made to FIG. 10B and FIG. 9A. The air pipe output panel 504 includes plural channels CH1-CH4, in which each of the channels CH1-CH4 is for control one wet process apparatus WA. For example, each of the channels CH1-CH4 includes an air pipe interface 504DV, an air pipe interface 504SV, and an air pipe interface 504GO. In some embodiments, the air pipe interface 504DV is configured to control a flow control device for draining liquids from the process bath. In some embodiments, the air pipe interface 504SV is configured to control a flow control device for supplying liquids into the process bath. In some embodiments, the air pipe interface 504GO is configured to control a flow control device for purging the process bath. In some embodiments, the air pipe interface 504DV, an air pipe interface 504SV, and an air pipe interface 504GO are outlets that outputs gas, and the air pipe output panel 504 includes a gas inlet 504GI for introducing the gas to the air pipe interface 504DV, an air pipe interface 504SV, and an air pipe interface 504GO.

In some embodiments of the present disclosure, two or more of the pipe interfaces 504DV, 504SV, and 504GO of one of the channels CH1-CH4 are respectively coupled to two or more flow control devices of one wet etch apparatus WA (e.g., the flow control devices WAV1 and WAV2) through suitable gas lines (e.g., gas lines GL1 and GL2). Through the configuration, the flow rates of liquid/gas through the two or more flow control devices (e.g., the flow control devices WAV1 and WAV2) can be respectively controlled by the two or more of the air pipe interfaces 504DV, 504SV, and 504GO of said one of the channels CH1-CH4.

In some embodiments where the wet process apparatus WA corresponds to the wet etch apparatus 200 and the flow control devices WAV1 and WAV2 respectively correspond to the flow control devices V22 and V23 in FIGS. 3A-3C, the air pipe interface 504DV and the air pipe interface 504SV are respectively coupled with the flow control devices V23 and V22 in FIGS. 3A-3C. Stated differently, in FIGS. 3A-3C, a flow rate of the etching solution ES through the flow control device V23 can be controlled by the air pipe interface 504DV, and a flow rate of the inactive solution WS through the V22 can be controlled by the air pipe interface 504SV.

In some embodiments where the wet process apparatus WA corresponds to the rinse apparatus 300 and the flow control devices WAV1 and WAV2 respectively correspond to the flow control device V32 and V33 in FIGS. 6A-6C, and the air pipe interface 504DV and the air pipe interface 504GO are respectively coupled with the flow control devices V33 and V32 and in FIGS. 6A-6C. Stated differently, in FIGS. 6A-6C, a flow rate of the rinsing solution RS through the flow control device V33 can be respectively controlled by the air pipe interface 504DV, and a flow rate of purging gas through the flow control device V32 can be controlled by the air pipe interface 504GO.

FIG. 10C is a top view of a manual button panel 510 of the control module 500 of FIG. 10A. Reference is made to FIG. 10C and FIG. 9A. The manual button panel 510 includes plural channels CH1-CH4. As discussed in FIG. 10B, each of the channels CH1-CH4 is for control one wet process apparatus WA in a manual mode. For example, each of the channels CH1-CH4 includes a manual operation button 510DB and a manual operation button 510SB. The manual operation buttons 510DB and 510SB can also be referred to as a liquid drain button and a water supply button, respectively. The manual operation button 510DB/510SB is a self-locking button switched with backlight indicator (e.g., light emitted diodes (LED)). When the button is pressed, it is locked in the ON state and the backlight indicator lights up. When the button is pressed again, it is released and returns to the OFF state, and the backlight indicator does not light.

The button 510DB is configured to control the output of the air pipe interface 504DV. If the button 510DB is pushed (e.g., at ON state), the air pipe interface 504DV outputs gas to turn on a flow control device (e.g., the flow control device V23 or V33) for draining liquids from the process bath. If the button 510DB is released (e.g., at OFF state), the air pipe interface 504DV does not output gas, and the flow control device for draining liquids from the process bath (e.g., the flow control device V23 or V33) is at off state.

The button 510SB is configured to control the output of the air pipe interface 504SV. If the button 510SB is pushed, the air pipe interface 504SV outputs gas to turn on a flow control device (e.g., the flow control device V22) for supplying liquids into the process bath. If the button 510SB is not pushed, the air pipe interface 504SV does not output gas, and the flow control device for supplying liquids into the process bath (e.g., the flow control device V22) is at off state.

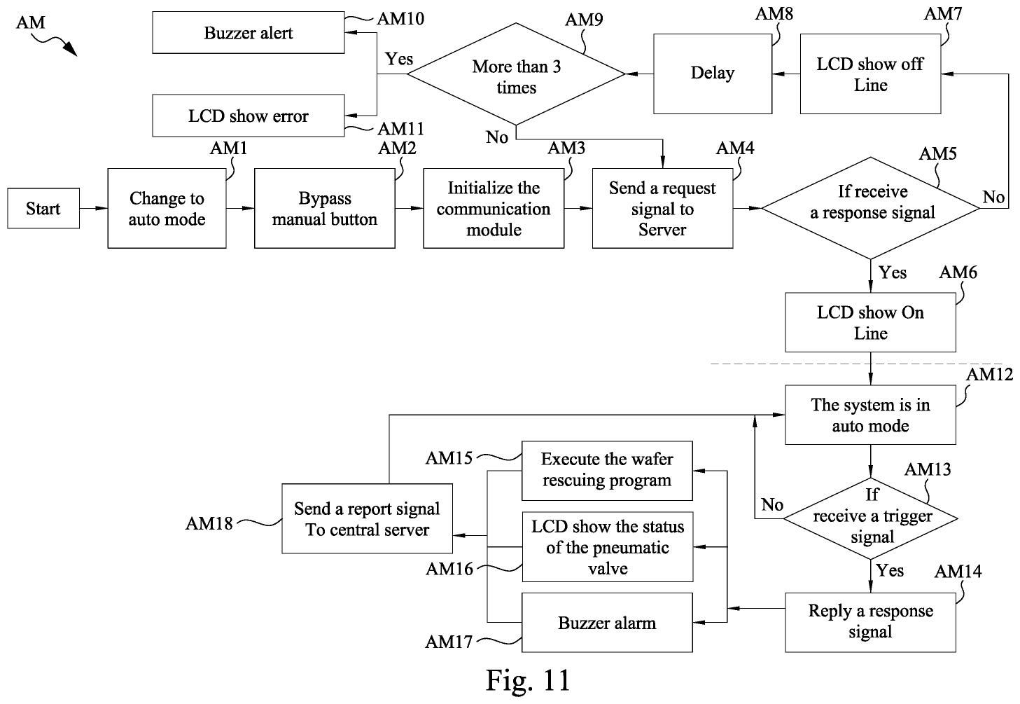

FIG. 11 is a flow chart of a method AM for automatically controlling a wet etch/rinse apparatus according to some embodiments of the present disclosure. Reference is made to FIG. 11 and FIG. 9A. The method AM may include steps AM1-AM18. It is understood that additional steps may be provided before, during, and after the steps shown in FIG. 11, and some of the steps described can be replaced or eliminated for additional embodiments of the method AM. The order of the operations/processes may be interchangeable.

The method AM begins at the step AM1 where the mode switch 513 is changed to an automatic (auto) mode. Then, when it is changed to the auto mode, the manual button panel 510 is bypassed at step AM2. Then, the method AM proceeds to step AM3, where the control module 500 initialize the communication module to the central server 410, and then sent a request signal to the central server 410 at step AM4. If the control module 500 receives a response signal from the central server 410 at step AM5, the communication with the central server 410 is established, and the LCD touch screen 509 may show some ON Line information at step AM6. If the control module 500 does not receives a response signal from the central server 410 at step AM5, the communication with the central server 410 is not established, the LCD touch screen 509 may show some OFF Line information at step AM7. Then, the method AM proceeds to step AM8, the control module 500 delays a certain time (e.g., about 10 seconds to about 50 seconds), and then goes to step AM9, where the steps AM4 and AM5 are repeated. If the steps AM4 and AM5 are repeated over several times (e.g., 2 times or 3 times), the method AM goes to steps AM10 and AM11, where the buzzer 511 would alarm, and the LCD touch screen 509 show error information. When the communication between the control module 500 and the central server 410 is successfully established, the control module 500 considered as being in auto mode at step AM12. The dashed line between the steps AM5 and AM indicates a boundary between an initialization process and a recipe implement.

When odds occur in the real-time signals, the controller WAC of the wet process apparatus WA can send an alarm signal A1 to the central server 410 to indicate an abnormal condition of the wet process apparatus WA. Then, the central server 410 can check if the alarm signal A1 is of specified alarm signals. If the alarm signal A1 is of the specified alarm signals, the central server 410 can send a trigger signal TS1 to the control module 500.

If the control module 500 receives the trigger signal TS1 at step AM13, the method AM proceeds to steps AM14-AM17. At step AM14, the control module 500 would send a response signal, e.g., to the central server 410. At step AM15, the control module 500 would execute the wafer rescuing program, which corresponds to the wafer rescuing process in FIG. 1. At step AM16, LCD touch screen 509 can show the status of the pneumatic valves (e.g., the drain valve (e.g., the valve V22 in FIGS. 3A-3C) and the supply valve (e.g., the valve V23 in FIGS. 3A-3C)). At step AM17, the buzzer 511 may alarm. After the steps AM14-AM17 are initiated, the method AM proceeds to step AM18, the control module 500 can send a report signal to the central server 410 to tell the central server 410 that the wafer rescuing program is initiated. A user may know information from the central server 410, and then go to check the wet process apparatus WA, repair the wet process apparatus WA, recover the wet process, or/and push the alarm and program reset button 514. If the control module 500 does not receive the trigger signal TS1 at step AM13, the method AM proceeds back to step AM12.

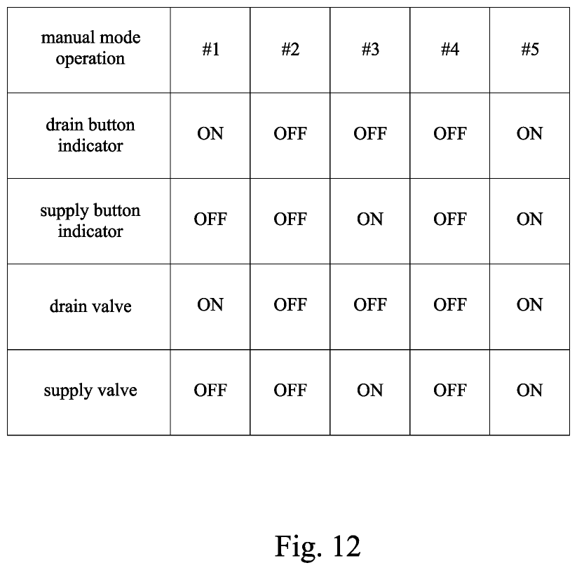

FIG. 12 is a chart showing various operations of the control module 500 under the manual mode according to some embodiments of the present disclosure. Reference is made to FIGS. 12 and 10C. In the manual mode operations #1, the liquid drain button 510DB is pushed, and the water supply button 510SB is released. In the manual mode operations #2, the liquid drain button 510DB is released, and the water supply button 510SB is released. In the manual mode operations #3, the liquid drain button 510DB is released, and the water supply button 510SB is pushed. In the manual mode operations #4, the liquid drain button 510DB is released, and the water supply button 510SB is released. In the manual mode operations #5, the liquid drain button 510DB is pushed, and the water supply button 510SB is pushed. The top two rows show the ON/OFF states of backlight indicators of these buttons, which can reveal the ON/OFF states of the buttons.

The bottom two rows show the status of the pneumatic valves. For example, the bottom two rows show the ON/OFF states of the drain valve (e.g., the valve V22 in FIGS. 3A-3C) and the supply valve (e.g., the valve V23 in FIGS. 3A-3C). Thus, by manually pressing or releasing the liquid drain buttons 510DB and 510SB, the drain valve (e.g., the valve V22 in FIGS. 3A-3C) and the supply valve (e.g., the valve V23 in FIGS. 3A-3C) can be controlled, the wafers can be rescued in a manual control manner.

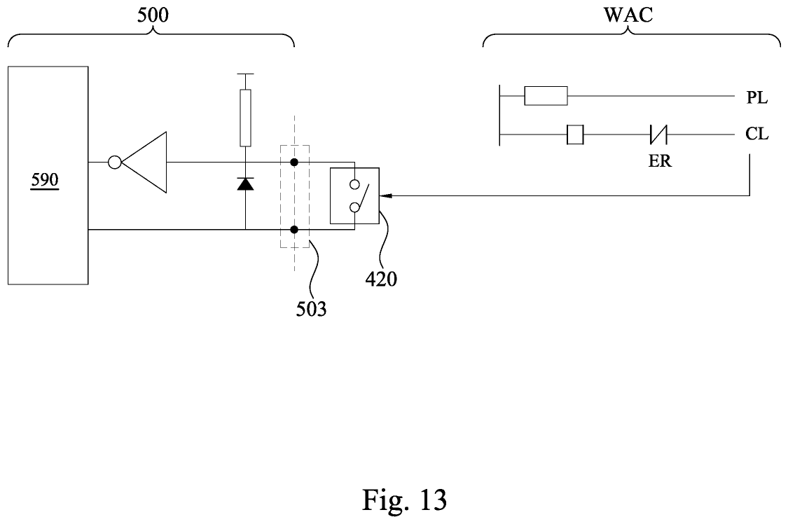

FIG. 13 is a circuit diagram of an emergency mode according to some embodiments of the present disclosure. The controller WAC of the wet process apparatus WA may include a power rail PL and/or a CPU error monitoring line CL. The monitor device 420 can be electrically connected to the power rail PL and/or a CPU error monitoring line CL for determine whether there is an error (e.g., the CPU error ER). The monitor device 420 can be connected to the interlock interface 503 of the control module 500. If there is an error (e.g., the CPU error ER) detected by the monitor device 420, the monitor device 420 may turn off, resulting a high resistance signal, which serve as a trigger signal TS2 (referring to FIG. 9C). The control module 500 can receive the trigger signal TS2, and trigger the wafer rescue program. The control module 500 can include a suitable control logic 590 electrically connected to the monitor device 420. The emergency program is used to monitor the unexpected conditions of the tool. During normal operation, the tool's control system controls a normally-on monitor device 420, and the control logic 590 inputs a low voltage. When the wet controller WAC of the wet process apparatus WA is abnormal, the monitor device 420 is released (e.g., off), the control logic 590 inputs a high voltage, all channels execute the defined wafer rescuing program, and the buzzer alarms at the same time, and for the auto and/or manual mode, an alarm command will be sent to the central server 410.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the system defines a wafer rescuing process, which is designed differently for different chemicals, and it has been proven that these processes is the best way to handle the situation of the wafer over-dip in the Wet Bench Tool. Another advantage is that the system designs multiple channels to control many kinds of pneumatic valves in the Wet Bench Tool, which allow users to customized wafer rescuing process function. Another advantage is that the system has self-diagnosis function to avoid the system failure. It will keep monitoring the status of the controller. The status includes but not limited to the air pressure, the power voltage and the MCU heart beat signal. If the controller detects the status abnormal, it will send the error message to the Factory Server, and the buzzer will alarm. Another advantage is that the system is programmable. The function of each linked pneumatic valve in the chemical bath module can be combined into different steps for different chemical scenarios. Each wafer rescuing program is defined by the duration and sequence of these steps. The sequence of steps can also be set to a loop. Another advantage is that the system can receive the command from the Factory Server to trigger the wafer rescuing process. Also, it can send the alarm message to the Factory Server. Another advantage is that the utmost eliminate the damage of the film and structure on the wafer for the over-dip caused by the Wet Bench Tool's abnormal. Another advantage is that the risk of manual handling by engineer is reduced, which can ensure personal safety.

According to some embodiments of the present disclosure, a method includes placing a wafer in a process bath filled with a process solution; determining whether the wafer is in the process bath after a pre-set process time after placing the wafer in the process bath; and in response the determination determines that the wafer is in the process bath after the pre-set process time, draining the process solution from the process bath while the wafer is in the process bath.

According to some embodiments of the present disclosure, a method includes placing a wafer in a process bath of a wet process apparatus, wherein the process bath is filled with a process solution; providing a trigger signal to a control module; and performing a wafer rescue process using the control module after the control module receives the trigger signal, wherein the wafer rescue process comprises: draining the process solution from the process bath.

According to some embodiments of the present disclosure, a system comprises a wet process apparatus and a control module. The wet process apparatus includes a process bath, a drain line fluidly connected to the process bath, and a first pneumatic valve coupled to the drain line. The control module is external to the wet process apparatus. The control module includes a first air pipe interface fluidly connected with the first pneumatic valve.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
placing a wafer in a process bath filled with a process solution;
determining whether the wafer is in the process bath after a pre-set process time after placing the wafer in the process bath; and
in response the determination determines that the wafer is in the process bath after the pre-set process time, draining the process solution from the process bath while the wafer is in the process bath.

2. The method of claim 1, wherein the process solution is an etching solution.

3. The method of claim 2, further comprising:
after draining the process solution from the process bath, supplying an inactive solution to the process bath, while the wafer is placed in the process bath.

4. The method of claim 1, wherein the process solution is a rinsing solution.

5. The method of claim 4, further comprising:
after draining the process solution from the process bath, purging the process bath by providing a gas into the process bath, while the wafer is placed in the process bath.

6. The method of claim 1, wherein draining the process solution from the process bath comprises:
removing the process solution by a drain line fluidly coupled to a bottom of the process bath.

7. The method of claim 1, wherein the process bath comprises an inner bath and an outer bath, the inner bath is disposed in the outer bath, and draining the process solution from the process bath comprises:
draining the process solution from the inner bath; and
draining the process solution from the outer bath.

8. A method, comprising:
placing a wafer in a process bath of a wet process apparatus, wherein the process bath is filled with a process solution;
providing a trigger signal to a control module; and
performing a wafer rescue process using the control module after the control module receives the trigger signal, wherein the wafer rescue process comprises:
draining the process solution from the process bath.

9. The method of claim 8, wherein the trigger signal is provided by a central sever, wherein the central sever receives an alarm signal from the wet process apparatus.

10. The method of claim 8, wherein the trigger signal is provided by a monitor device electrically coupled with the wet process apparatus.

11. The method of claim 8, wherein draining the process solution from the process bath comprises:
using the control module, turning on a first pneumatic valve coupled to a drain line fluidly connected to the process bath.

12. The method of claim 8, wherein the wafer rescue process further comprises:
supplying an inactive solution to the process bath.

13. The method of claim 12, wherein supplying the inactive solution to the process bath comprises:
using the control module, turning on a second pneumatic valve coupled to a supply line fluidly connected to the process bath.

14. The method of claim 8, wherein the wafer rescue process further comprises:
purging the process bath.

15. The method of claim 12, wherein purging the process bath comprises:
using the control module, turning on a third pneumatic valve coupled to a gas line fluidly connected to a spraying nozzle above the process bath.

16. A system, comprising:
a wet process apparatus comprising a process bath, a drain line fluidly connected to the process bath, and a first pneumatic valve coupled to the drain line; and
a control module external to the wet process apparatus, wherein the control module comprises a first air pipe interface fluidly connected with the first pneumatic valve.

17. The system of claim 16, wherein the wet process apparatus further comprises a supply line fluidly connected to the process bath and a second pneumatic valve coupled to the supply line, and the control module further comprises a second air pipe interface fluidly connected with the second pneumatic valve.

18. The system of claim 16, wherein the wet process apparatus further comprises a gas line fluidly connected to a spray nozzle above the process bath and a third pneumatic valve coupled to the gas line, and the control module further comprises a third air pipe interface fluidly connected with the third pneumatic valve.

19. The system of claim 16, wherein the process bath comprises an inner bath and an outer bath, the inner bath is disposed in the outer bath, and the drain line is fluidly connected to the inner bath and the outer bath.

20. The system of claim 16, further comprising:
a monitoring device electrically coupled with the wet process apparatus and the control module.
